(19) United States
(12) Patent Application Publication
(10) Pub. No.: US 2007/0004079 A1
(43) Pub. Date: Jan. 4, 2007

(54) Method for making contact through via contact to an offset contactor inside a cap for the wafer level packaging of FBAR chips

(76) Inventors: Frank S. Geefay, Cupertino, CA (US); Richard C. Ruby, Menlo Park, CA (US)

Correspondence Address: AVAGO TECHNOLOGIES, LTD., P.O. BOX 1920, DENVER, CO, 80201-1920, US

(21) Appl. No.: 11/173,367

(22) Filed: Jun. 30, 2005

(51) Int. Cl. H01L 21/00; H01L 21/4763; H01L 21/44

(52) U.S. Cl. 438/106; 438/619; 438/612

(57) ABSTRACT

A device package includes a device substrate and a cap mounted on the device substrate. The device substrate includes a contact pad. The cap defines a via with a slightly sloped sidewall through the cap, a contactor extending from an interior surface of the cap, a contactor pad over the contactor, a via pad on the interior surface of the cap over the via and coupled to the contactor pad, and a via contact over the exterior surface of the cap and in the via coupled to the via pad. The contactor is offset from the via. When the cap is mounted on the device substrate, the contactor pad on the contactor is pressed and cold welded onto the contact pad on the device substrate.

### DESCRIPTION OF RELATED ART

A thin film semiconductor process can be used to create a film bulk-wave acoustic resonator (FBAR), which consists of an electrode-piezoelectric-electrode sandwich suspended in air. When an alternating electrical potential is applied across the electrode-piezoelectric-electrode sandwich, the entire piezoelectric layer expands and contracts, creating a vibration. This resonance is in the body (bulk) of the material, as opposed to being confined to the surface as in the case for Surface Acoustic Wave (SAW) devices. Such an acoustic resonator may act as a filter in the duplexers for cellular handsets.

To build a FBAR device, a pit is formed on a substrate and then filled with a sacrificial material. A stack consisting of a bottom electrode, a piezoelectric, and a top electrode is formed over the filled pit. A passivation layer is then formed above the stack. The top electrode and the piezoelectric are patterned, and the sacrificial material is removed to suspend the stack over the pit to form the FBAR device.

The FBAR device may be enclosed in a hermetic micro-size cap (“microcap”) wafer-level package. The package is formed by bonding a cap wafer to a device wafer. The bonding areas are seal rings formed around each device and vias for receiving via contacts or plugs. The package is then singulated from the bonded cap wafer and device wafer.

### SUMMARY

In one embodiment of the invention, a device package includes a device substrate and a cap mounted on the device substrate. The device substrate includes a contact pad. The cap defines a via with a slightly sloped sidewall through the cap, a contactor extending from an interior surface of the cap, a contactor pad over the contactor, a via pad on the interior surface of the cap over the via and coupled to the contactor pad, and a via contact over the exterior surface of the cap and in the via coupled to the via pad. The contactor is offset from the via. When the cap is mounted on the device substrate, the contactor pad on the contactor is pressed and cold welded onto the contact pad on the device substrate.

### BRIEF DESCRIPTION OF THE DRAWINGS

FIG. 1 is a flowchart of a method for fabricating a device package in one embodiment of the invention.

FIGS. 2 to 9 illustrate cross-sections of a device package formed using the method of FIG. 1 in one embodiment of the invention.

Use of the same reference numbers in different figures indicates similar or identical elements.

### DETAILED DESCRIPTION

U.S. Pat. No. 6,777,263 describes a device package where a seal ring structure is formed around a via that passes through the cap wafer and down to the device wafer. A via contact is formed in the via to contact a via pad on the device wafer. The seal ring structure incorporates a treaded surface coated with a metal to hermetically seal the via where they make contact with the via pads on the device wafer. The seal may break if the seal ring structure is not properly bonded. In addition, the seal ring structure is relatively large in size and therefore requires a large via pad on the device wafer. For example, the areas consumed by the via pads can be as much as 50% of the device area for a small device around 0.5 millimeter square. This size of the via pad reduces the number of devices that can be manufactured per wafer. Thus, an alternative is provided for providing an electrical connection to the device within the device package.

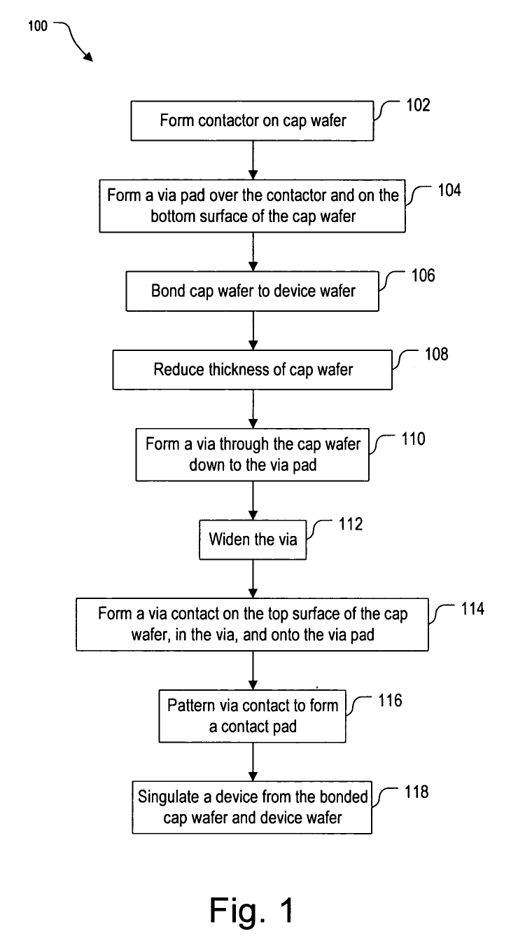

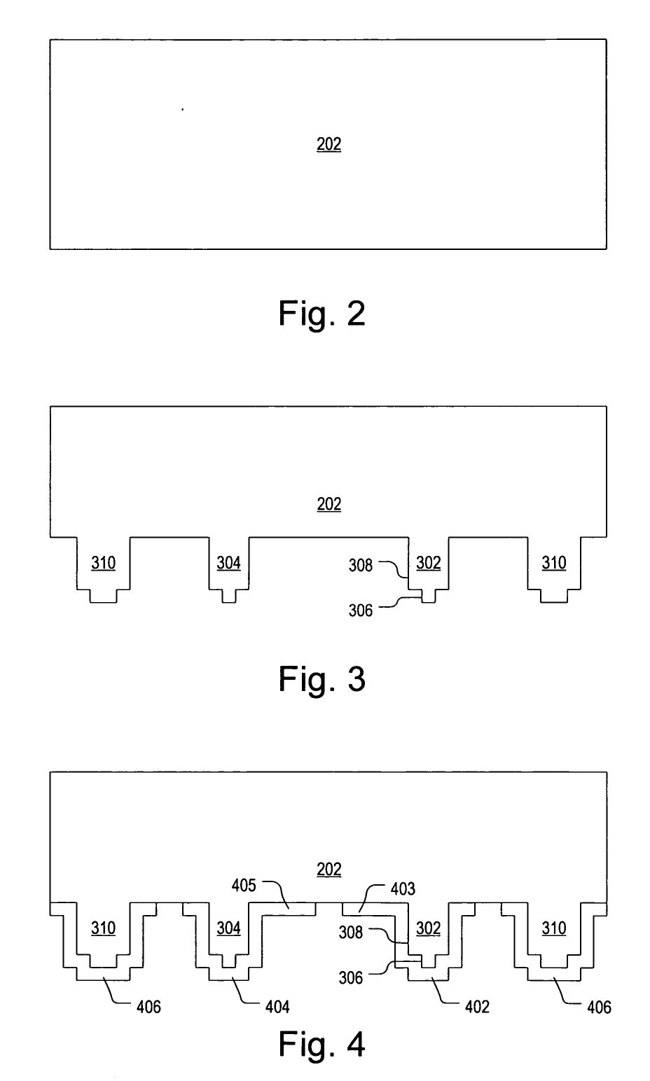

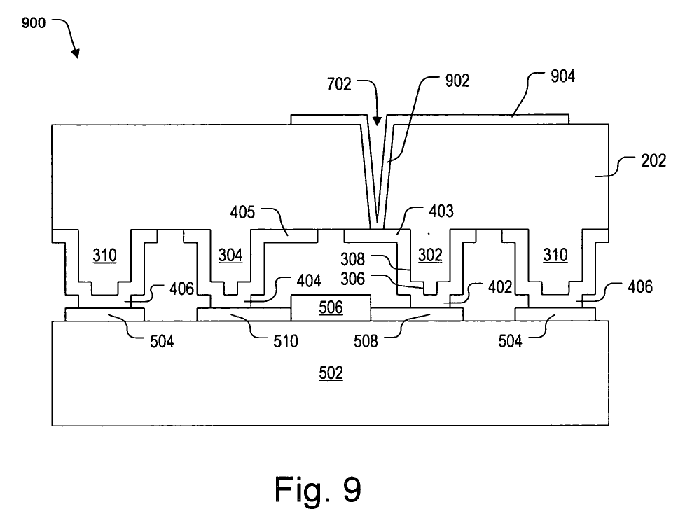

FIG. 1 is a flowchart of a method 100 for fabricating a device package 900 (FIG. 9) in one embodiment of the invention. Method 100 starts with a cap wafer 202 shown partially in FIG. 2. In one embodiment, cap wafer 202 is a silicon wafer. As one skilled in the art understands, the following steps are performed in parallel for multiple device packages in a wafer-level process.

In step 102 as shown in FIG. 3, contactors 302 and 304 are formed on the interior surface (e.g., the bottom surface) of cap wafer 202. Contactors 302 and 304 are protrusions that extend from the bottom surface of cap wafer 202. A continuous seal ring 310 is also formed on the bottom surface of cap wafer 202. Each of the contactors and seal ring may consist of a gasket 308 (labeled only for contactor 302) and a tread 306 on gasket 308. Tread 306 may consist of a single narrow finger on gasket 308. In one embodiment, cap wafer 202 is etched to form seal ring 310 and contactors 302 and 304 using the same two masks. Alternatively, contactors 302 and 304 may consist of a simple rectangular or circular protrusion from the bottom surface of cap wafer 202 without any gasket or tread.

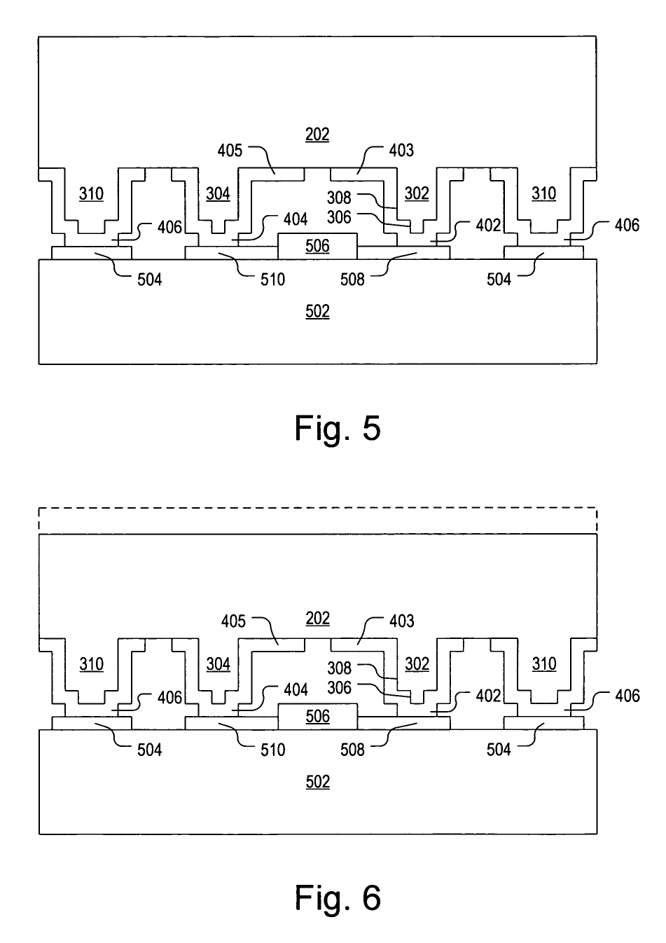

In step 104 as shown in FIG. 4, a contactor pad 402 is formed over contactor 302 and a via pad 403 is formed on the bottom surface of cap wafer 202. Contactor pad 402 is to be connected to a contact pad 508 (FIG. 5) and via pad 403 is to be connected to a via contact 902 (FIG. 9). Similarly, a contactor pad 404 is formed over contactor 304 and a via pad 405 is formed on the bottom surface of cap wafer 202. Contactor pad 404 is to be connected to a contact pad 510 (FIG. 5) and via pad 405 is to be connected to a via pad (not illustrated). A bonding pad 406 is also formed over seal ring 310.

Although shown in close proximity, the via pad can be located away from the contactor pad where the two pads are electrically connected by a trace. In one embodiment, pads 402, 403, 404, 405, and 406 are gold pads formed by a metal etch process using the same mask.

In step 106 as shown in FIG. 5, cap wafer 202 is mounted onto a device wafer 502. Specifically, seal ring 310 is pressed onto a continuous bonding pad 504 formed on the interior surface (e.g., the top surface) of device wafer 502 around a device 506. In one embodiment, cap wafer 202 and device wafer 502 are compressed together until a cold weld bond forms between (1) bonding pad 406 on seal ring 310 and (2) bonding pad 504 on device wafer 502. Typical bonding conditions for such an embodiment include compressing the wafers together using 60 to 120 megapascals of pressure at a temperature ranging from 300 to 400° C. for 2 minutes to 1 hour. In other embodiments, cap wafer 202 and device wafer 502 may be bonded by solder, glass, or adhesive with modification of the seal ring materials.

At the same time seal ring 310 is pressed onto bonding pad 504, contactors 302 and 304 are also pressed onto contact pads 508 and 510, respectively. A cold weld bond may be formed between (1) contactor pads 402/404 on contactors 302/304 and (2) contact pads 508/510 on device wafer 502, respectively. In one embodiment, device 506 is a film bulk-wave acoustic resonator (FBAR) that has been formed on device wafer 502. Contact pads 508 and 510 provide the electrical connection to device 506. In one embodiment, bonding pad 504 and contact pads 508 and 510 are gold pads formed by photolithography.

In step 108 as shown in FIG. 6, cap wafer 202 is reduced to the appropriate thickness. In one embodiment, the exterior surface (e.g., the top surface) of cap wafer 202 is ground by a standard wafer grind process.

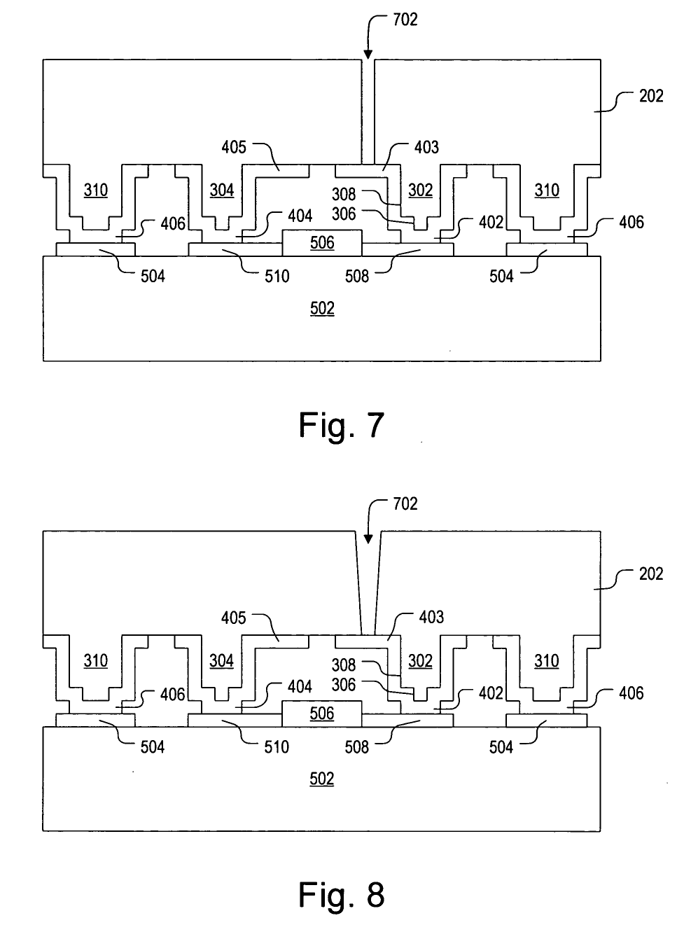

In step 110 as shown in FIG. 7, a very narrow via 702 with substantially vertical sidewall is formed through cap wafer 202 and down to via pad 403 on the bottom surface of cap wafer 202. Via 702 is offset from contactor 302 by a distance determined by design requirements. Via 702 can have a variety of shapes (e.g., rectangle or round) and orientations. In one embodiment, via 702 is formed using an anisotropic dry deep silicon etch (e.g., the Bosch process). For clarity, only a single via is illustrated although another similar via can be formed down to the other via pad 405.

In step 112 as shown in FIG. 8, via 702 is widened to provide a sloped sidewall. In one embodiment, narrow via 702 is widened with an isotropic dry silicon etch so it has slightly sloped sidewall angled between 80 and 87 degrees from the inside of the cap wafer 202.

In step 114 as shown in FIG. 9, a via contact 902 is formed on the top surface of cap wafer 202, down via 702, and onto via pad 403. In one embodiment, via contact 902 is formed using an electroplating process where a seed layer is deposited over the top surface of cap wafer 202 and into via 702, and gold is electroplated onto the seed layer. In such an embodiment, the slightly sloped via sidewall helps the gold seed layer to coat the sidewalls down via 702.

In step 116, via contact 902 is patterned to form an outer contact pad 904 used for connecting device 506 to external circuitry. In one embodiment, via contact 902 is patterned by photolithography and etching the plated and seed metals. Although shown in close proximity, outer contact pad 904 can be located away from via contact 902 where the two pads are electrically connected by a trace.

In step 118, device package 900 is singulated from bonded cap wafer 202 and device wafer 502 along with the other device packages manufactured in parallel. Note that in FIG. 9, the same reference number is used to identify the individual cap of device package 900 and the cap wafer, and the same reference number is used to identify the individual device substrate of device package 900 and the device wafer.

As described above, device package 900 provides an alternative to the seal ring structure around the via described in U.S. Pat. No. 6,777,263. Contact pads 508 and 510 on device wafer 502 are also much smaller than the former contact pads.

Various other adaptations and combinations of features of the embodiments disclosed are within the scope of the invention. Although silicon is used for cap wafer 202 and device wafer 502, other material such as gallium arsenide (GaAs) may be used. Numerous embodiments are encompassed by the following claims.

What is claimed is:

1. A device package, comprising:
a device substrate comprising a contact pad and a device;
a cap mounted on the device substrate, the cap defining a via with a slightly sloped sidewall, the cap comprising:
a contactor extending from an interior surface of the cap facing the device substrate, wherein the via is offset from the contactor;
a contactor pad located over the contactor, wherein the contactor pad contacts the contact pad;
a via pad on the interior surface of the cap under the via, wherein the via pad is coupled to the contactor pad;
a via contact over an exterior surface of the cap and in the via, wherein the via contact is coupled to the via pad.

2. The device package of claim 1, wherein the contactor comprises a tread.

3. The device package of claim 1, wherein the contactor comprises a gasket and a tread on the gasket.

4. The device package of claim 1, wherein the device comprises a film bulk-wave acoustic resonator (FBAR).

5. The device package of claim 1, wherein:
the device substrate further comprises a first bonding pad around the device;
the cap further comprises a seal ring extending from the interior surface of the cap and a second bonding pad over the seal ring, wherein the seal ring with the second bonding pad mounts on the first bonding pad.

6. The device package of claim 1, wherein:
the cap further comprises another contact pad on the exterior surface of the cap, wherein the another contact pad is coupled to the via contact.

7. A method for making a device package, comprising:
forming a contactor on an interior surface of a cap wafer;
forming a contactor pad over the contactor;
forming a via pad on the interior surface of the cap wafer, wherein the via pad is coupled to the contactor pad;
forming a device on a device wafer;
mounting the cap wafer on the device wafer, wherein the contactor pad on the contactor contacts a contact pad on an interior surface of the device wafer facing the cap wafer;
forming a via with a slightly sloped sidewall through the cap wafer to the via pad, wherein the via is offset from the contactor; and
forming a via contact on an exterior surface of the cap wafer and in the via, wherein the via contact is coupled to the via pad.

8. The method of claim 7, wherein said forming a contactor comprising etching the cap wafer to form the contactor.

9. The method of claim 8, wherein the contactor comprises a tread.

10. The method of claim 8, wherein the contactor comprises a gasket and a tread on the gasket.

11. The method of claim 7, wherein said forming a contactor pad and a via pad comprises a metal etch process.

12. The method of claim 7, wherein said mounting the cap wafer comprises forming a cold weld bond between a seal ring around the device on the interior surface the cap wafer and a bonding pad on the interior surface of the device wafer.

13. The method of claim 7, after said mounting the cap wafer on the device wafer and prior to said forming a via, further comprising grinding the cap wafer to reduce its thickness.

14. The method of claim 7, wherein said forming a via comprises using an anisotropic etch followed by an isotropic etch to provide the slightly sloped sidewall in the via.

15. The method of claim 7, wherein said forming a via contact comprises forming a seed metal and electroplating a metal on the seed metal.

16. The method of claim 7, wherein the device comprises a film bulk-wave acoustic resonator (FBAR).

17. The method of claim 7, further comprising singulating the device package from the bonded cap wafer and the device wafer.

18. The method of claim 7, further comprising:
forming another contact pad on the exterior surface of the cap, wherein the another contact pad is coupled to the via contact.
